(19) United States
(12) Patent Application Publication
(10) Pub. No.: US 2014/0328032 A1
(43) Pub. Date: Nov. 6, 2014

(54) CHIP ARRANGEMENT, CHIP CARD ARRANGEMENT AND METHOD FOR MANUFACTURING A CHIP ARRANGEMENT

(71) Applicant: Infineon Technologies AG, Neubiberg (DE)

(72) Inventors: Frank Pueschner, Kelheim (DE); Juergen Hoegerl, Regensburg (DE); Thomas Spoettl, Mintraching (DE)

(73) Assignee: Infineon Technologies AG, Neubiberg (DE)

(21) Appl. No.: 14/267,941

(22) Filed: May 2, 2014

(30) Foreign Application Priority Data
May 3, 2013 (DE) 10 2013 104 567.7

(51) Int. Cl. H05K 1/02; H01L 23/00

(52) U.S. Cl. CPC H05K 1/028; H01L 24/95
USPC 361/749; 438/106

(57) ABSTRACT

A chip arrangement may include: a flexible carrier; a first supporting structure and a second supporting structure for strengthening a region of the carrier, the first supporting structure being arranged on a first side of the carrier and the second supporting structure being arranged opposite from the first supporting structure on a second side of the carrier; and a chip arranged on the first side of the carrier, the chip being carried and supported by means of the supporting structures and by means of the carrier. The second supporting structure may extend at least by the same amount as the chip along the directions parallel to the surface of the carrier.

### CROSS-REFERENCE TO RELATED APPLICATION

This application claims priority to German Patent Application Serial No. 10 2013 104 567.7, which was filed May 3, 2013, and is incorporated herein by reference in its entirety.

### TECHNICAL FIELD

Various embodiments relate generally to a chip arrangement, a chip card arrangement and to a method for manufacturing a chip arrangement.

### BACKGROUND

In general, chip cards, known as smart cards, may be exposed to mechanical loads in daily use, and so they should preferably be robust with respect to mechanical loads. In particular, a chip module or a chip, which may be arranged in a chip card housing, may be destroyed or damaged when mechanical loads occur, such that for example the functional capability of the chip or the chip module may be impaired or suppressed.

### SUMMARY

A chip arrangement may include: a flexible carrier; a first supporting structure and a second supporting structure for strengthening a region of the carrier, the first supporting structure being arranged on a first side of the carrier and the second supporting structure being arranged opposite from the first supporting structure on a second side of the carrier; and a chip arranged on the first side of the carrier, the chip being carried and supported by means of the supporting structures and by means of the carrier. The second supporting structure may extend at least by the same amount as the chip along the directions parallel to the surface of the carrier.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIGS. 1A to 1C respectively show a schematic representation of a chip arrangement in a cross-sectional view or side view, according to various embodiments;

FIG. 1D shows a detailed schematic representation of a chip arrangement in a cross-sectional view or side view, according to various embodiments;

FIGS. 2A and 2B respectively show a schematic representation of a chip arrangement, according to various embodiments, which includes at least one antenna structure, in a cross-sectional view or side view;

FIG. 3 shows a schematic flow diagram of a method for manufacturing a chip arrangement, according to various embodiments;

FIGS. 4A to 4F respectively show a schematic representation of a chip arrangement at various points in time during manufacture, in a cross-sectional view or side view, according to various embodiments;

FIGS. 4E and 4F respectively show a schematic representation of a chip arrangement in a cross-sectional view or side view, according to various embodiments;

FIG. 5 shows a schematic representation of a chip arrangement in an exploded representation, according to various embodiments;

FIGS. 6A to 6C respectively show a detailed schematic representation of a supporting structure or strengthening structure in a plan view, according to various embodiments; and

FIGS. 6D to 6G respectively show a detailed schematic representation of a supporting structure or strengthening structure in a cross-sectional view or side view, according to various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

In the following detailed description, reference is made to the accompanying figures, which form part of this description and in which specific embodiments in which the invention can be implemented are shown for purposes of illustration. In this respect, directional terminology such as for instance “up”, “down”, “forward”, “backward”, “front”, “rear”, etc. is used with respect to the orientation of the figure(s) described. Since components of embodiments may be positioned in a number of different orientations, the directional terminology serves for the purposes of illustration and is not in any way restrictive. It goes without saying that other embodiments can be used and structural or logical changes may be made without departing from the scope of protection of the present invention. It goes without saying that the features of the various embodiments that are given by way of example and described herein can be combined with one another, unless specifically stated otherwise. The following detailed description should therefore not be understood in a restrictive sense, and the scope of protection of the present invention is defined by the appended claims.

In the context of this description, the terms “connected” and “coupled” are used for describing both a direct and an indirect connection and a direct or indirect coupling. In the figures, identical or similar elements are provided with identical designations, insofar as this is expedient.

One aspect of various embodiments can clearly be seen in providing a chip arrangement on the basis of a flexible carrier and a flexible chip, having a strengthening structure or a plurality of strengthening structures for mechanically strengthening the chip and/or the flexible carrier. In this case, the chip arrangement may provide a chip module for a chip card, for example the chip arrangement 100 may provide a chip module with a contactless interface for a chip card arrangement. The chip arrangement may for example be set up in such a way that the chip is arranged on a carrier, it being possible for the carrier to be stabilized by means of a number of strengthening structures (or supporting structures) in a region in the vicinity of the chip, for example in a region in which the chip is attached. In this case, the chip arrangement may for example be set up in such a way that tearing of the carrier from the edge of the strengthening structure and/or from the edge of the chip can be avoided, or at least the susceptibility of the chip arrangement to tearing of the carrier from the edge of the strengthening structure and/or from the edge of the chip can be reduced. Furthermore, a chip arrangement or a chip card that can withstand a relatively high mechanical load without for example breaking up and/or without for example the electrical function of the chip arrangement being impaired may be provided. This can clearly be achieved for example by it being possible for the chip and the strengthening structure (supporting structure) to be arranged and/or set up relative to one another in such a way that the chip arrangement does not have a shearing edge or punching edge, for example that the edge of the chip and/or the edge of the strengthening structure does not form a shearing edge or punching edge, since a shearing edge or punching edge can promote tearing of the carrier, whereby for example conductor tracks on the carrier and the carrier itself may be damaged. It can in this way be prevented for example that, on account of a straight shearing edge or punching edge, the carrier tears under a mechanical load and the electrical function of the chip arrangement is impaired.

According to various embodiments, a chip arrangement may include the following: a flexible carrier; a first supporting structure and a second supporting structure for strengthening a region of the carrier, the first supporting structure being arranged on a first side of the carrier and the second supporting structure being arranged opposite from the first supporting structure on a second side of the carrier, a chip arranged on the first side of the carrier, the chip being carried and supported by means of the supporting structures and by means of the carrier, the second supporting structure extending at least by the same amount as the chip along the directions parallel to the surface of the carrier.

Furthermore, the second supporting structure may extend further than the chip along the directions (or along one direction) parallel to the surface of the carrier.

Furthermore, the second supporting structure may extend further than the first supporting structure at least along one direction parallel to the surface of the carrier.

According to various embodiments, a chip arrangement may include the following: a flexible carrier; a first supporting structure and a second supporting structure for strengthening a region of the carrier, the first supporting structure being arranged on a first side of the carrier and the second supporting structure being arranged opposite from the first supporting structure on a second side of the carrier, a chip arranged on the first side of the carrier, the chip being carried and supported by means of the supporting structures and the carrier, the second supporting structure extending further than the chip along the directions parallel to the surface of the carrier and/or extending further than the first supporting structure at least along one direction parallel to the surface of the carrier.

Furthermore, according to various embodiments, the chip arrangement may include at least one antenna arranged on the carrier, the at least one antenna being connected in an electrically conducting manner to the chip.

Furthermore, according to various embodiments, the second supporting structure may include a plurality of clearances in an edge region of the second supporting structure.

Furthermore, according to various embodiments, the second supporting structure may extend further than the first supporting structure along all directions parallel to the surface of the carrier. In other words, the second supporting structure may extend further than the first supporting structure parallel to the surface of the carrier, such that the edge of the first supporting structure and the edge of the second supporting structure do not form a common edge (shearing edge or punching edge).

Furthermore, according to various embodiments, the first supporting structure may extend further than the chip along all directions parallel to the surface of the carrier. In other words, the first supporting structure may extend further than the chip parallel to the surface of the carrier, such that the edge of the first supporting structure and the edge of the chip do not form a common edge (shearing edge or punching edge).

Furthermore, according to various embodiments, the first supporting structure may be arranged between the carrier and the chip.

Furthermore, according to various embodiments, the first supporting structure may include at least one metal and/or a metal alloy.

Furthermore, according to various embodiments, the second supporting structure may include at least one metal and/or a metal alloy.

Furthermore, according to various embodiments, the first supporting structure and the second supporting structure may be formed from the same material.

Furthermore, according to various embodiments, the first supporting structure and the second supporting structure and the antenna may be formed from the same material.

Furthermore, according to various embodiments, the chip arrangement may include a further layer arranged between the chip and the carrier, it being possible for the further layer to include at least one solder and/or an adhesive.

Furthermore, according to various embodiments, the first supporting structure and the second supporting structure may have a thickness in a range from approximately 5 μm to approximately 100 μm. Furthermore, according to various embodiments, the first supporting structure or the second supporting structure may have a thickness in a range from approximately 5 μm to approximately 100 μm.

Furthermore, according to various embodiments, the chip may have a chip thickness that may be less than approximately 110 μm. Furthermore, according to various embodiments, the chip may have a chip thickness that may be less than approximately 200 μm. Furthermore, the chip may have a thickness such that the chip can be bent and/or elastically deformed by means of a mechanical load.

Furthermore, according to various embodiments, the chip may include at least one protective layer that covers at least one surface of the chip. Furthermore, according to various embodiments, the at least one protective layer may include a plastic and/or a polymer.

Furthermore, according to various embodiments, the carrier may include a plastic and/or a polymer.

Furthermore, according to various embodiments, the carrier may have a thickness in a range from approximately 1 μm to approximately 100 μm.

According to various embodiments, a method for manufacturing a chip arrangement may include the following: the forming of a first supporting structure on a first surface of a carrier, the forming of a second supporting structure on a surface of the carrier that is opposite from the first surface, such that a region of the carrier between the supporting structures is stabilized; and the attachment of a chip on the first side of the carrier, such that the chip is carried by means of the supporting structures and by means of the carrier, the second supporting structure extending at least by the same amount as the chip along the directions parallel to the surface of the carrier.

Furthermore, in the method for manufacturing a chip arrangement, the forming of the second supporting structure and the attachment of the chip may be performed in such a way that the second supporting structure extends further than the chip along at least one direction parallel to the surface of the carrier.

Furthermore, in the method for manufacturing a chip arrangement, the forming of the first supporting structure and the forming of the second supporting structure may be performed in such a way that the second supporting structure extends further than the first supporting structure along at least one direction parallel to the surface of the carrier.

According to various embodiments, a method for manufacturing a chip arrangement may include the following: the forming of a first supporting structure on a first surface of a carrier, the forming of a second supporting structure on a surface of the carrier that is opposite from the first surface, such that a region of the carrier between the supporting structures is stabilized; and the attachment of a chip on the first side of the carrier, the chip being carried by means of the supporting structures and the carrier, the second supporting structure extending further than the chip along at least one direction parallel to the surface of the carrier and/or the second supporting structure extending further than the first supporting structure along at least one direction parallel to the surface of the carrier.

Furthermore, the method for manufacturing a chip arrangement may include the forming of at least one antenna on the carrier, it being possible for the at least one antenna to have an electrically conductive connection to the chip.

According to various embodiments, a chip card arrangement may include the following: a chip card housing; and a chip arrangement, as described herein, it being possible for the chip arrangement to be attached to the chip card housing.

Furthermore, according to various embodiments, the chip card housing may include at least one antenna, which may be inductively coupled to the at least one antenna of the chip arrangement.

Furthermore, the chip may extend further than the first supporting structure along the directions parallel to the surface of the carrier. In other words, the chip may extend further than the first supporting structure parallel to the surface of the carrier, such that the edge of the first supporting structure and the edge of the chip do not form a common edge (shearing edge or punching edge).

Furthermore, at least one surface and/or one or more of the side faces of the first supporting structure may be covered by means of an underfill material.

Furthermore, an underfill material may be introduced between the chip and the first supporting structure in such a way that the first supporting structure is at least partially surrounded by the underfill material.

Furthermore, an underfill material may be introduced between the chip and the first supporting structure in such a way that at least one of the side faces of the first supporting structure is surrounded or covered by the underfill material.

A chip arrangement according to various embodiments is described below. In order to provide a chip arrangement, a chip module, a chip card and/or a chip housing that is intended for example to be insensitive or resistant to a mechanical load, flexible materials and/or flexible components may for example be used. A chip arrangement may for example include a flexible carrier on which a flexible chip is arranged and/or attached, such that this flexible (or bendable or deformable) chip arrangement can compensate for a mechanical load without for example breaking or being damaged.

At least the following may be understood herein as meaning a mechanical load: a mechanical pressure, a mechanical stress, a torsional stress, a flexural stress, a deformation, a strain, a bending, a tensile stress, a compressive stress, an elastic deformation, a point load or force, and the like.

A stiffness may be understood herein as meaning the resistance of a body or a component of the chip arrangement 100 to an elastic deformation, for example on account of a force or a torque. The stiffness of a component or a body may for example depend on the material involved and the geometry. The compliance (or flexibility) may be considered herein as being the inverse of the stiffness.

Furthermore, a flexible body or a flexible component, such as it is described herein, can make a reversible deformation possible.

According to various embodiments, the carrier for providing a chip arrangement may be formed from a flexible material and/or have a corresponding thickness, such that the carrier is flexible. The carrier may for example have a thickness of less than or equal to 100 μm, such that the carrier can be flexible or bendable. The chip that can for example be arranged on the flexible carrier may have a thickness of less than or equal to 100 μm and include silicon. Such a thin or ultra-thin silicon chip may be flexible (for example bendable or reversibly deformable), such that the chip can withstand a mechanical load, for example without breaking.

According to various embodiments, apart from the mechanical stability as such of a chip and/or a chip arrangement, the stability of the electrical connections and line routings of a chip and/or a chip arrangement may also play a part. A chip arrangement (a chip, a chip module) may for example include one or more metalization structures (metallizations or metalization layers), including for example an electrical line structure and a dielectric layer structure, which may make possible and/or provide the electrical functionality of the chip arrangement. The metalization structures or other electrical conductor structures (for example an antenna structure) may have a lower flexibility than the silicon base of the chip itself, and consequently be susceptible to damage. Furthermore, a metalization structure may be under mechanical stress, which may have been introduced into the metalization structure as a result of manufacturing. Therefore, for example, too great a flexibility of the chip or the chip arrangement may in turn be disadvantageous, since for example a metalization structure or line routing cannot withstand too great a deformation of the chip and/or the chip arrangement. Therefore, a chip arrangement (or a chip module, or a chip), of which the mechanical properties are substantially defined by the mechanical properties of the chip and the thickness thereof, may have a greater mechanical flexibility, and consequently withstand a higher mechanical load without breaking, with decreasing thickness of the chip. A silicon chip may for example be brittle and tend to break if the thickness of the chip exceeds a certain thickness, for example a thickness of approximately 100 μm. On the other hand, for example, a metalization structure of the chip or the chip arrangement may lose the electrical functionality under a mechanical load, although the chip or the chip arrangement may for example not yet be broken. For example, the chip may bend under a mechanical load on account of its mechanical flexibility, the chip consequently not being destroyed, but the electrical lines in the metalization structure of the chip may in this case be interrupted. Therefore, the line routing of a chip may make it necessary that at least the chip in a chip arrangement is mechanically strengthened, for example by means of a local strengthening structure. In this case, a chip in a chip arrangement may for example be mechanically stabilized by means of a number of supporting structures. Furthermore, the stiffness of the carrier of the chip arrangement that for example carries the chip may be increased by means of one or more supporting structures at least in one region of the carrier.

In order to achieve improved stability of the chip arrangement or of the chip, the mechanical deformation properties (for example the stiffness) of the carrier, of the chip and/or of the strengthening structures may be adapted. In this case, a balance can be provided between mechanical protection from breaking and protection of the metalization structure of the chip or the metalization structure of the chip arrangement.

According to various embodiments, one region of the carrier may be strengthened (supported and/or stiffened), for example the region in which the chip can be arranged, while the remaining region of the carrier may be flexibly designed, for example the remaining region of the carrier in which an antenna structure can be arranged. This may be achieved for example by providing a flexible carrier (for example with a thickness in a range from approximately 10 μm to approximately 50 μm), it being possible for a metal layer that is relatively thick in comparison with the thickness of the carrier (for example with a thickness in a range from approximately 30 μm to approximately 50 μm) to be arranged respectively on the upper side and the underside of the carrier, it being possible for the metal layers on the upper side and the underside of the carrier to be of a similar size. The metal layers may in this case serve as supporting structures, stiffening structures and/or strengthening structures for the chip, the chip arrangement and/or a region of the carrier. Furthermore, for example, at least one supporting structure (metal layer) may be set up in such a way that it supports, stiffens and/or strengthens the chip, the chip arrangement and/or a region of the carrier.

In the event that the chip and the supporting structures are arranged congruently one above the other, such that a common shearing edge or punching edge is produced, although the protection of the chip and the chip arrangement can be realized, it may be accompanied by the disadvantage that the carrier may tend to tear at the edge of the stiffening structure, on account of the common shearing edge or punching edge, possibly causing a tearing-off of a conductor track, which may for example connect the chip to an antenna (or coil).

Therefore, according to various embodiments, the carrier may include or consist of a material that has an improved mechanical tearing property (for example polyimide instead of a glass-epoxy system, such as for example FR4). This allows the effect of the tearing of the carrier to be reduced, but not eliminated entirely. Therefore, according to various embodiments, the stiffening structure may be set up in such a way that the forming of a shearing edge or tearing edge within the chip arrangement is avoided.

According to various embodiments, there is provided a chip arrangement that offers better protection of the chip arrangement and the components of the chip arrangement from a mechanical load, such that for example the chip arrangement (or a component of the chip arrangement) can withstand a higher mechanical load, such that the electrical functionality of the chip arrangement can be preserved, and/or such that the carrier of the chip arrangement does not tear more easily on account of a shearing edge.

According to various embodiments, there is provided a chip arrangement that has a high resistance to a mechanical load and includes a supporting structure which is set up in such a way that, for example, a tearing of the carrier at the edge of the supporting structure and/or at the edge of the chip under a mechanical load is not promoted. In this case, the chip and the supporting structures may be arranged in relation to one another in such a way that the outer edges of the supporting structures and the outer edges of the chip do not form a common edge (shearing edge or punching edge). In other words, the supporting structures may be set up in such a way that a tearing of the carrier under a mechanical load is not promoted on account of an unfavorable relative arrangement of the supporting structures and the chip.

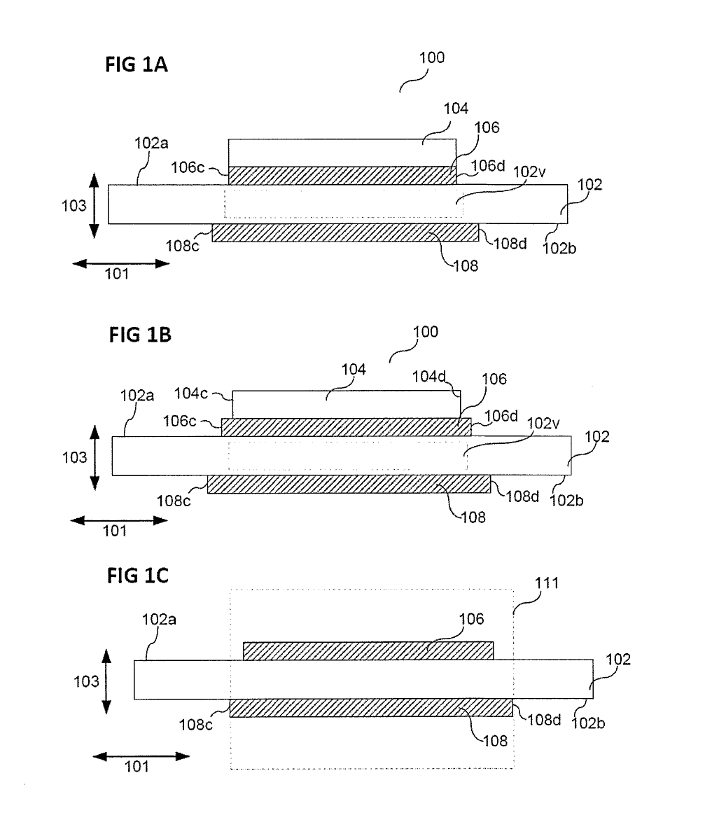

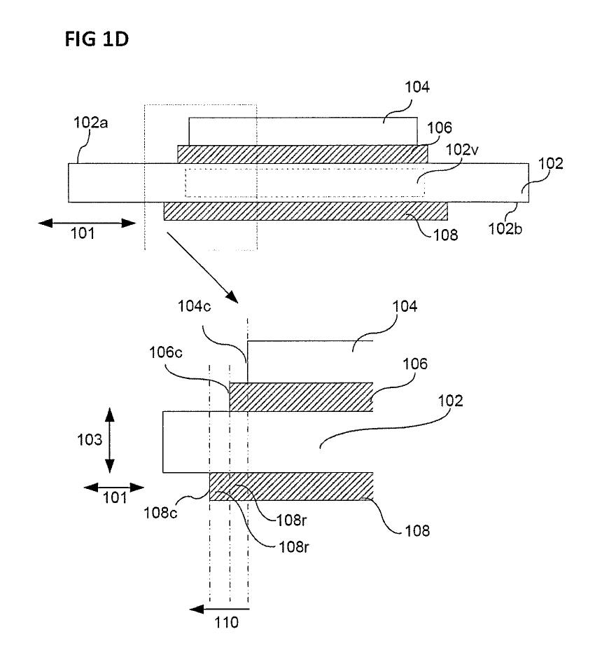

FIG. 1A shows in a schematic cross-sectional view or side view a chip arrangement 100, according to various embodiments.

According to various embodiments, a chip arrangement 100 may include the following: a flexible carrier 102; a first supporting structure 106 and a second supporting structure 108 for strengthening a region 102v of the carrier 102, the first supporting structure 106 being arranged on a first side of the carrier 102a and the second supporting structure 108 being arranged opposite from the first supporting structure 106 on a second side 102b of the carrier 102, a chip 104 arranged on the first side 102a of the carrier 102, the chip 104 being carried and supported by means of the supporting structures 106, 108 and by means of the carrier 102, the second supporting structure 108 extending at least by the same amount as the chip 104 along the directions parallel to the surface of the carrier 102.

According to various embodiments, a chip arrangement 100 may include the following: a flexible carrier 102; a first supporting structure 106 and a second supporting structure 108 for strengthening a region 102v of the carrier 102, the first supporting structure 106 being arranged on a first side of the carrier 102a and the second supporting structure 108 being arranged opposite from the first supporting structure 106 on a second side 102b of the carrier 102, a chip 104 arranged on the first side 102a of the carrier 102, the chip 104 being carried and supported by means of the supporting structures 106, 108 and by means of the carrier 102, the second supporting structure 108 extending further than the chip 104 along the directions 101 parallel to the surface of the carrier 102 and/or extending further than the first supporting structure 106 at least along one direction 101 parallel to the surface of the carrier 102.

In other words, the first supporting structure 106 and the second supporting structure 108 may be arranged on opposite sides 102a, 102b of the carrier 102, such that they support (or stabilize or stiffen) a region 102v of the carrier 102 between the supporting structures 106, 108. In this case, the lateral faces, for example the first side face 106c of the first supporting structure 106 and the first side face 108c of the second supporting structure 108, may have an offset in relation to one another in the direction 101.

According to various embodiments, the lateral extent of the first supporting structure 106 along one direction 101 parallel to the carrier surface 102a, 102b may be less than the lateral extent of the second supporting structure 108. Furthermore, the first side face 106c of the first supporting structure 106 and the first side face 108c of the second supporting structure 108 may have an offset in relation to one another in the direction 101; and/or the second side face 106d, opposite from the first side face 106c, of the first supporting structure 106 and the second side face 108d, opposite from the first side face 108c, of the second supporting structure 108 may have an offset in relation to one another in the direction 101.

According to various embodiments, the first supporting structure 106 and the second supporting structure 108 may be arranged oppositely in relation to one another on the carrier 102 in such a way that the side faces 106c, 108c of the supporting structures 106, 108 are not arranged in line with one another along the direction 103 perpendicular to the surface 102a, 102b of the carrier 102, such that for example the side faces 106c, 108c of the supporting structures 106, 108 and the associated edges of the side faces 106c, 108c of the supporting structures 106, 108 do not form a common shearing edge and/or punching edge.

Furthermore, all of the lateral delimiting surfaces (the delimiting surfaces along the directions 101 parallel to the carrier surface 102a, 102b) of the first supporting structure 106 and of the second supporting structure 108 may respectively have an offset in relation to one another along the directions 101 parallel to the carrier surface 102a, 102b, such that for example the lateral delimiting surfaces of the supporting structures 106, 108 and the associated edges of the lateral delimiting surfaces of the supporting structures 106, 108 do not form a common shearing edge and/or punching edge.

As represented in FIG. 1B in a schematic cross-sectional view or side view, the lateral delimiting surfaces of the chip (the delimiting surfaces of the chip along the direction 101 parallel to the carrier surface 102a, 102b) may also have an offset respectively in relation to the lateral delimiting surfaces of the supporting structures 106, 108, such that for example the lateral delimiting surfaces of the supporting structures 106, 108 and the lateral delimiting surfaces of the chip do not form a common in-line surface.

In the event that, for example, two side faces 106c, 108c have an offset in relation to one another, the side faces 106c, 108c may not for example be arranged in line with one another. The spatial arrangement of the associated edges of the side faces is correspondingly provided by the spatial arrangement of the side faces 106c, 106d, 108c, 108d of the supporting structures 106, 108 and the side faces 104c, 104d of the chip 104.

FIG. 1C shows a carrier 102 on which respectively a first supporting structure 106 may be arranged on a first surface 102a of the carrier 102 and a second supporting structure 108 may be arranged on the second surface 102b of the carrier 102.

Furthermore, for example, the second supporting structure 108 may form a region 111, the first supporting structure 106 being arranged within the region of the first supporting structure 106. According to various embodiments, the lateral delimiting surfaces 108c, 108d of the second supporting structure 108 (the lateral delimitation of the second supporting structure 108 along the direction 101 parallel to the carrier surface 102a, 102b) may form a region 111 along the direction 103 (perpendicular to the carrier surface 102a, 102b), it being possible for the first supporting structure 106 to be at least partially arranged in the region of the second supporting structure 108, it being possible for the first supporting structure 106 and the second supporting structure 108 to be arranged respectively on the opposite sides 102a, 102b of the carrier 102.

Furthermore, the chip 104 may be arranged within the region 111, which is defined by the delimiting surfaces 108c, 108d of the second supporting structure 108 along the direction 103.

According to various embodiments, the chip 104 may be arranged on the first supporting structure 106.

According to various embodiments, the chip 104 may be a chip module or a flexible chip module, for example a flexible chip in a flexible chip housing or a flexible chip that is stabilized by means of one or more flexible layers.

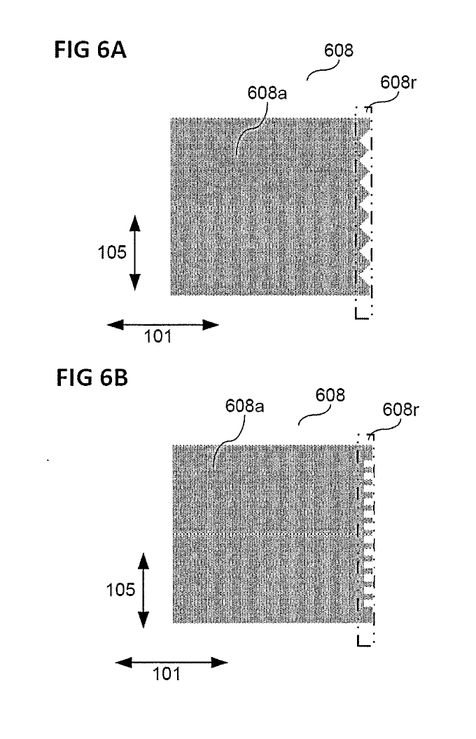

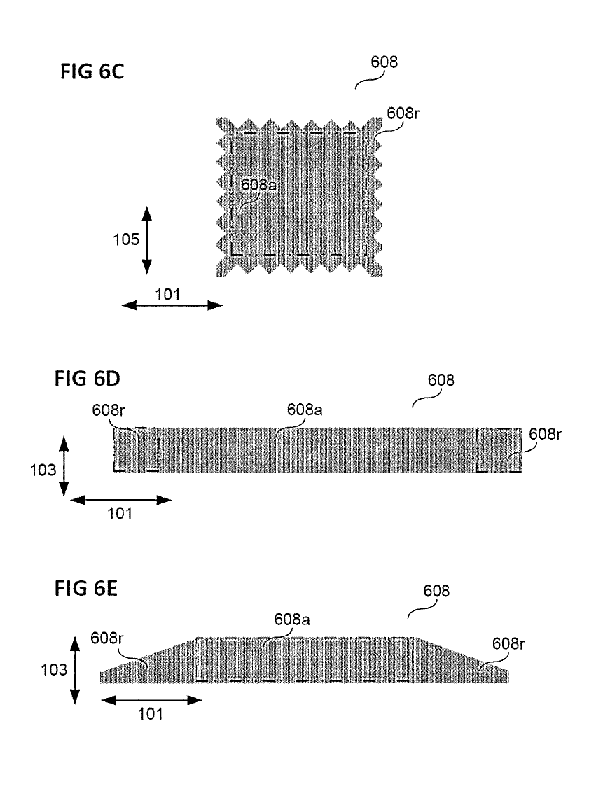

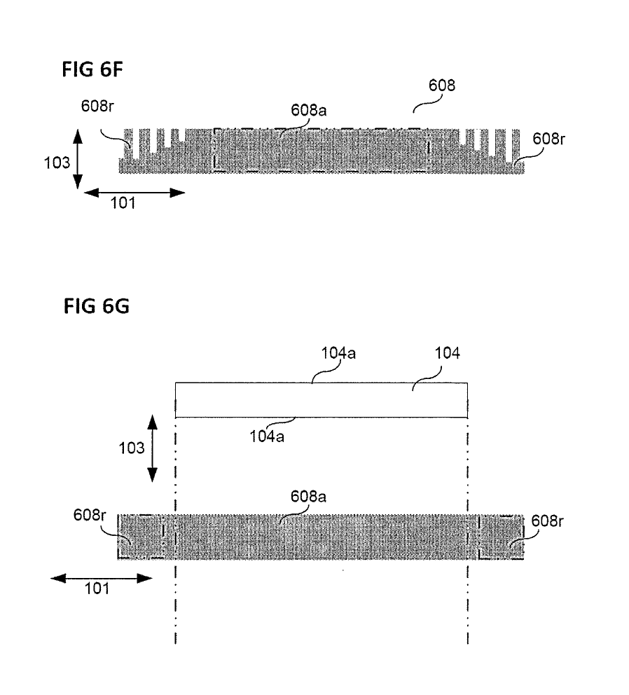

According to various embodiments, the second supporting structure 108 may include a plurality of clearances in an edge region of the second supporting structure 108, as is represented in FIG. 6A to FIG. 6G and described later. In this case, for example, the edge region of the second supporting structure 108 may be defined by the offset of the side faces 108c, 108d of the second supporting structure 108 with respect to the side faces 106c, 106d of the first supporting structure 106.

As schematically represented in FIG. 1D, the edge region 108r of the second supporting structure 108 may include the part of the second supporting structure 108 or be defined by the part of the second supporting structure 108 that extends further in the direction 110 than for example the chip 104 and/or the first supporting structure 106. In this case, the direction 110 may lie parallel to the carrier surface 102a, 102b and point away from the chip 104 with respect to the lateral delimitation 104c of the chip 104 and/or point away from the first supporting structure 106 with respect to the lateral delimitation of the first supporting structure 106. Furthermore, the second supporting structure 108 may be set up in such a way, compare FIG. 6A to FIG. 6G, that the mechanical properties (for example the stiffness) of the edge region 108r of the second supporting structure 108 are different from the mechanical properties of the rest of the second supporting structure 108.

Furthermore, the edge region 108r of the second supporting structure 108 may include a different material than the rest of the regions of the second supporting structure 108, such that the mechanical properties of the edge region 108r can be adapted in such a way that a tearing of the carrier 102 under a mechanical load is prevented, or at least the carrier 102 can withstand a greater mechanical load before the carrier 102 tears. This can clearly be achieved by the edge region 108r of the second supporting structure 108 being able to have a greater flexibility (or lower stiffness), such that the edge 108c and/or the edge region 108r of the second supporting structure 108 has a less hard edge, and consequently the carrier 102 does not tear or become damaged under a mechanical load as a result of a hard edge.

According to various embodiments, the second supporting structure 108 may extend further than the first supporting structure 106 along all directions 101 parallel to the surface 102a, 102b of the carrier 102. In FIG. 1A and FIG. 1B, this is respectively represented schematically for one direction 101, it being possible for this representation to be transferred analogously to the other directions that lie within a plane, which may lie parallel to the carrier surface 102a, 102b. Clearly, the second supporting structure 108 can stabilize (or support, or stiffen) at least one region 102v of the carrier 102, the chip being arranged on the carrier 102 in such a way that the chip is carried and/or stabilized by the region 102v. Furthermore, the first supporting structure 106 may be arranged between the chip 104 and the carrier 102.

Furthermore, according to various embodiments, the first supporting structure may extend further than the chip 104 along all directions 101 parallel to the surface 102a, 102b of the carrier 102. In this case, the first supporting structure 106 may for example have at least one region that is formed by underfill material (underfilling material) or that includes underfill material.

According to various embodiments, the first supporting structure 106 may include or consist of at least one metal and/or a metal alloy.

According to various embodiments, the second supporting structure 108 may include or consist of at least one metal and/or a metal alloy.

Furthermore, the first supporting structure 106 and/or the second supporting structure 108 may include or consist of at least one of the following materials: a metal, a metallic material, an alloy, an intermetallic compound, copper, aluminum, titanium, titanium nitride, tungsten or doped silicon (polysilicon).

According to various embodiments, the first supporting structure 106 may have a thickness along the direction 103, perpendicular to the direction 101, where the direction 101 may point along the surface 102a, 102b of the carrier 102, in a range from approximately 5 μm to approximately 100 μm, for example a thickness in a range from approximately 10 μm to approximately 80 μm, for example in a range from approximately 20 μm to approximately 60 μm. According to various embodiments, the first supporting structure 106 may have a thickness of approximately 40 μm.

According to various embodiments, the second supporting structure 108 may have a thickness along the direction 103 in a range from approximately 5 μm to approximately 100 μm, for example a thickness in a range from approximately 10 μm to approximately 80 μm, for example in a range from approximately 20 μm to approximately 60 μm. According to various embodiments, the second supporting structure 106 may have a thickness of approximately 40 μm.

According to various embodiments, the stiffness of the supporting structures may consequently be greater than the stiffness of the carrier 102, such that one region of the carrier 102 may be stabilized by means of the supporting structures, it being possible for the remaining region of the carrier to remain flexible. In the remaining flexible region of the carrier there may be arranged for example an antenna or an antenna structure. Furthermore, the stiffness of the supporting structures may contribute to the chip 104 being stabilized, such that the chip 104 can be more resistant to a mechanical load.

According to various embodiments, the chip 104 may have a chip thickness along the direction 103, perpendicular to the direction 101, the direction 101 pointing along the surface 102a, 102b of the carrier 102, it being possible for the chip thickness to be less than approximately 110 μm, for example less than 100 μm, for example the chip thickness may lie in a range from 5 μm to approximately 100 μm.

According to various embodiments, the carrier 102 may be a substrate or a carrier film/foil, it being possible for the carrier 102 to include or consist of a plastic and/or a polymer. The carrier 102 may for example consist of polyimide or include polyimide. Furthermore, the carrier 102 may have a thickness along the direction 103, perpendicular to the direction 101, the direction 101 pointing along the surface 102a, 102b of the carrier 102, in a range from approximately 1 μm to approximately 100 μm, for example in a range from approximately 5 μm to approximately 50 μm, for example the carrier 102 may have a thickness in a range from approximately 20 μm to approximately 30 μm.

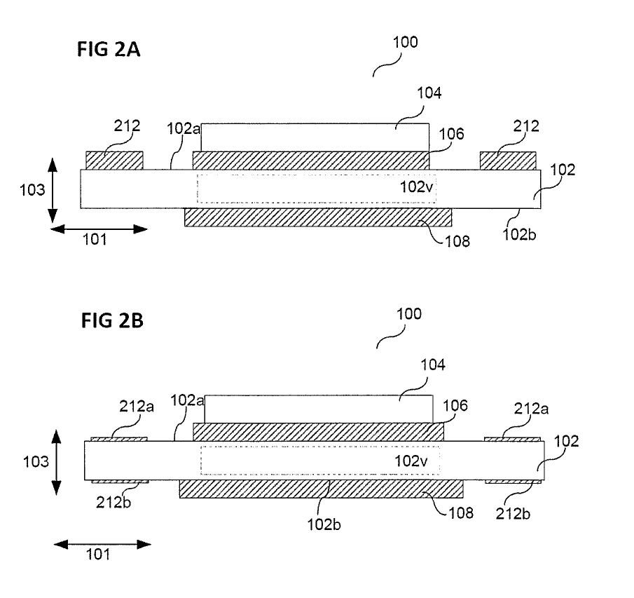

As represented in FIG. 2A and FIG. 2B, the chip arrangement may include at least one antenna 212, arranged on the carrier 102, the at least one antenna 212 being connected in an electrically conducting manner to the chip 104.

FIG. 2A shows a schematic cross-sectional view or side view of a chip arrangement 100, it being possible for the chip arrangement 100 to be set up in a way analogous to the foregoing description, and an antenna 212 (or antenna structure 212) being arranged on the carrier 102. The antenna 212 may for example be arranged on the side 102a of the carrier 102 on which the chip 104 is also arranged. In other words, the chip 104 and the antenna 212 may be arranged on the same side of the carrier 102. Furthermore, the antenna 212 may also be arranged on the side 102b of the carrier 102 that is opposite from the side 102a.

According to various embodiments, the antenna 212 or the antenna structure 212 may include or consist of at least one of the following materials: a metal, a metallic material, an alloy, an intermetallic compound, copper, aluminum, titanium, titanium nitride, tungsten, doped silicon (polysilicon), gold, silver, nickel, zinc or an aluminum-silicon alloy.

Furthermore, the antenna 212 or the antenna structure 212 may include or consist of a structured layer, for example a structured copper layer, that has been formed for example by means of copper-etching technology. Furthermore, the antenna 212 or the antenna structure 212 may include a structured aluminum layer that has been formed for example by means of aluminum-etching technology.

According to various embodiments, the second supporting structure 108 may be a contact structure (contact pad) or a part of a contact structure, which may for example be able to serve for transferring data between the chip 104 and a periphery. Furthermore, the second supporting structure 108 may be a contact structure or a part of a contact structure, for example a chip card contact pad in accordance with ISO 7816.

Furthermore, the chip arrangement 100 may also be set up in such a way that data transmission between the chip 104 and a periphery can take place contactlessly by means of the antenna 212. Furthermore, the chip arrangement 100 may have a number of antennas 212a, 212b, as illustrated in FIG. 2B. In this case, the first antenna 212a may be arranged on the first side 102a of the carrier 102 and the second antenna 212b may be arranged on the second side 102b of the carrier 102. It goes without saying that the one antenna 212 or the number of antennas 212a, 212b may be connected in an electrically conducting manner to the chip 104, such that a data transmission is possible.

Furthermore, the chip arrangement 100 may also be set up in such a way that data transmission between the chip 104 and a periphery can take place contactlessly by means of the antenna 212 and by means of a contact pad, this being known as a dual-interface chip card.

According to various embodiments, the chip arrangement 100 may include a housing, for example a chip card housing, such that the chip arrangement 100 can act as a chip card.

Furthermore, the chip arrangement 100 may be inserted into a housing, for example into a chip card housing, and/or be connected to a housing, for example to a chip card housing.

According to various embodiments, a chip card arrangement may be provided (on the basis of the chip arrangement 100 described herein), it being possible for the chip card arrangement to include the following: a chip card housing; and a chip arrangement 100, the chip arrangement being connected to the chip card housing.

In the event that the chip arrangement 100 includes an antenna 212, the chip card arrangement may include a chip card housing, it being possible for the chip card housing to include at least one antenna, which may be inductively coupled to the at least one antenna of the chip arrangement.

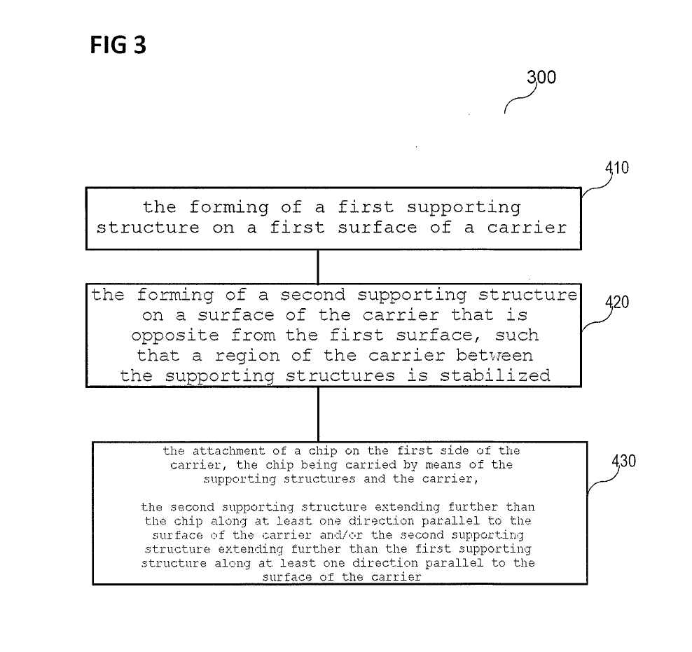

FIG. 3 shows a method 300 for manufacturing a chip arrangement in a schematic flow diagram, it being possible for the method to include the following: in 310, the forming of a first supporting structure 106 on a first surface 102a of a carrier 102; in 320, the forming of a second supporting structure 108 on a surface 102b of the carrier 102 that is opposite from the first surface 102a, such that a region 102v of the carrier 102 between the supporting structures 106, 108 is stabilized; and, in 330, the attachment of a chip 104 on the first side 102a of the carrier 102, the chip 104 being carried by means of the supporting structures 106, 108 and by means of the carrier 102, the second supporting structure 108 extending further than the chip 104 along at least one direction 101 parallel to the surface 102a, 102b of the carrier 102 and/or the second supporting structure 108 extending further than the first supporting structure 106 along at least one direction 101 parallel to the surface 102a, 102b of the carrier 102.

Furthermore, a method for manufacturing a chip arrangement may include the following: the forming of a first supporting structure 106 on a first surface 102a of a carrier 102; the forming of a second supporting structure 108 on a surface 102b of the carrier 102 that is opposite from the first surface 102a, such that a region 102v of the carrier 102 between the supporting structures 106, 108 is stabilized; and the attachment of a chip 104 on the first side 102a of the carrier 102, the chip 104 being carried by means of the supporting structures 106, 108 and by means of the carrier 102, the second supporting structure 108 extending at least by the same amount as the chip 104 along the directions 101 parallel to the surface of the carrier 102.

Furthermore, according to various embodiments, the forming of the first supporting structure 106 on the surface 102a may be performed in such a way that the lateral extent of the first supporting structure 106 is less than the lateral extent of the chip 104, it being possible for the chip 104 to be attached on the first supporting structure 106 by means of an underfilling (an underfill process). In this case, for example, at least a part of the first supporting structure 106 may be enclosed by means of the underfill material. The underfill material may for example cover the sides 106c, 106d of the first supporting structure 106.

Furthermore, the method for manufacturing a chip arrangement may include the forming of at least one antenna 212 on the carrier 102, it being possible for the at least one antenna 212 to include an electrically conductive connection to the chip 104.

The underfill process (underfilling process) described herein may for example serve the purpose of attaching the chip 104 on the carrier 102 or on the first supporting structure 106 (for example by means of an adhesive underfilling material) and/or of electrically contacting the chip. For example, an electrically conducting connection between the chip and the antenna 212 or a contact pad may be necessary or provided, such that, when the chip is attached, at the same time the electrically conducting connection between the chip and the antenna 212 and/or between the chip 104 and a contact pad can be provided. The electrically conducting connection may take place for example by means of solder balls or by means of structured layers and/or plated-through holes (vias).

According to various embodiments, the first supporting structure 106 and the antenna 212 may for example be formed at the same time in a joint method step. Furthermore, the second supporting structure 108 and the antenna 212 may for example be formed at the same time in a joint method step.

Furthermore, according to various embodiments, the chip 104 may be attached on the first supporting structure 106 or on the carrier 102 by means of soldering.

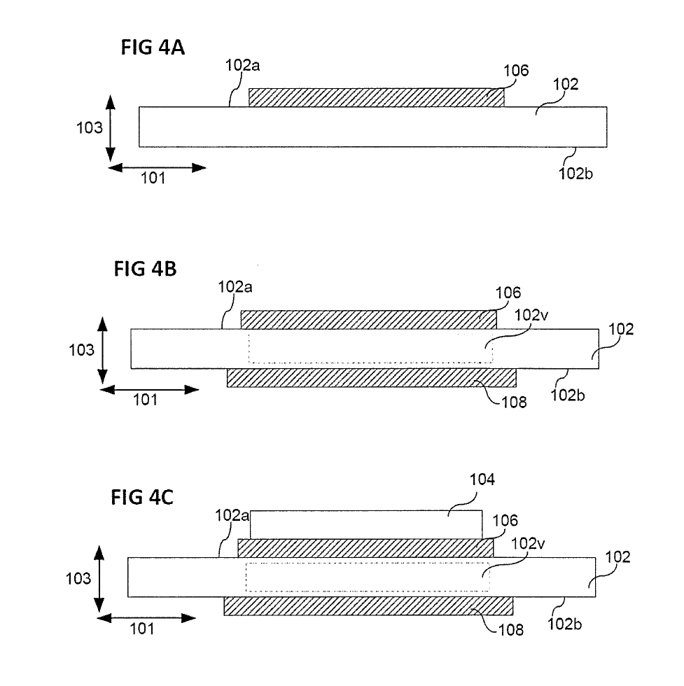

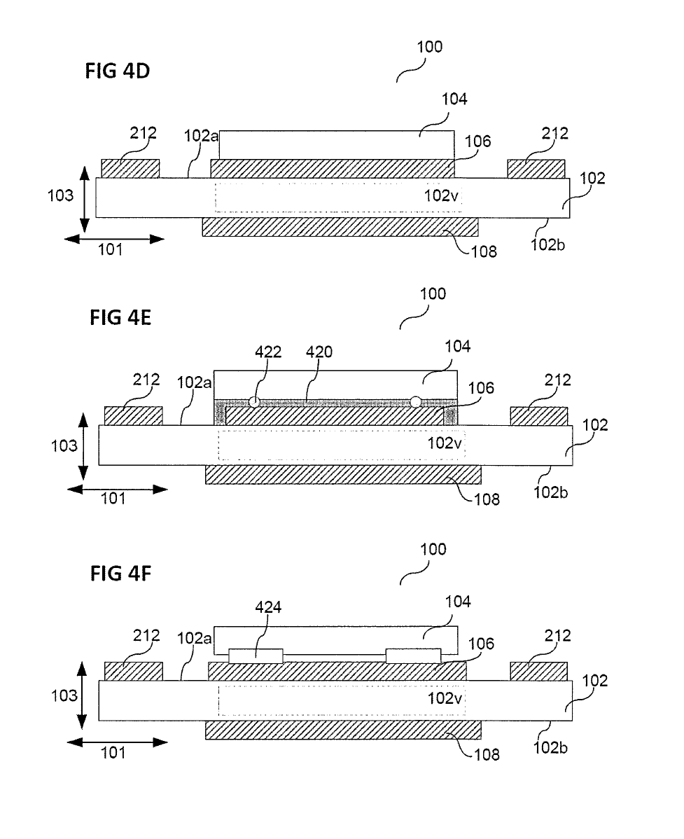

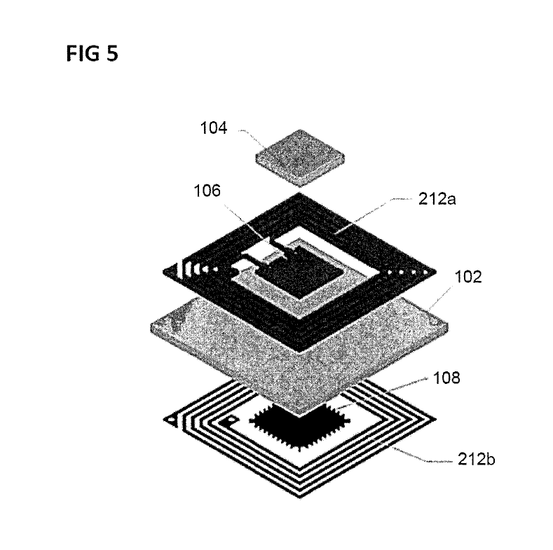

FIG. 4A to FIG. 4D respectively show a schematic representation of a chip arrangement at various points in time during a method 300 for manufacturing a chip arrangement 100 in a cross-sectional view or side view, according to various embodiments.

According to various embodiments, the carrier 102 and/or the chip arrangement 100 may be flexible, such that the method 300 can be carried out in a roll-to-roll method. A roll-to-roll method may make possible a low-cost, quick and efficient method for manufacturing the chip arrangement 100. According to various embodiments, a large number of chip arrangements 100 can be manufactured at the same time on a carrier, it being possible for example for the chip arrangements 100 of the large number of chip arrangements 100 to be separated or singulated after the method 300.

According to various embodiments, the steps of the method 300 may also be carried out in a different sequence, if this is expedient, for example in the following sequence of the individual process steps: 310, 330, 320 or 320, 310, 330.

FIG. 4A shows a schematic cross-sectional view or side view of a chip arrangement 100 including a carrier 102 and a first supporting structure 106 applied to one side 102a of the carrier 102, for example after the process step 310 of the method 300 has been carried out.

FIG. 4B shows a schematic cross-sectional view or side view of a chip arrangement 100 including a carrier 102, a first supporting structure 106 applied to one side 102a of the carrier 102 and a second supporting structure 108, the second supporting structure 108 having been formed on a second side 102b of the carrier 102, it being possible for the second side 102b of the carrier 102 to be opposite from the first side 102a, for example after the process step 310 and the process step 320 of the method 300 have been carried out.

According to various embodiments, the first supporting structure 106 and/or the second supporting structure 108 may be formed by means of chemical vapor deposition (CVD) or by means of physical vapor deposition (PVD). Furthermore, the first supporting structure 106 and/or the second supporting structure 108 may be formed by means of an electrochemical or galvanic process.

Furthermore, the forming of the first supporting structure 106 and/or of the second supporting structure 108 may include at least one or more of the following processes: a lithography process, an etching process, a structuring process, chemical-mechanical polishing (CMP), a layer depositing process (known as layering), a copper etching process or an aluminum etching process.

According to various embodiments, the first supporting structure 106 and/or the second supporting structure 108 may be formed by one or more deposited layers being structured, for example by means of an etching process or by means of a number of etching processes.

For example, a copper layer and/or an aluminum layer may be deposited on at least a part of the carrier 102. Furthermore, the copper layer (or aluminum layer) may be structured. According to various embodiments, a mask (for example a photolithography mask) may be applied to the carrier 102, such that at least one region of the carrier is correspondingly exposed, and the first supporting structure 106 and/or the second supporting structure 108 (for example a copper layer or aluminum layer) can subsequently be formed in the exposed regions of the carrier 102.

According to various embodiments, the first supporting structure 106 and/or the second supporting structure 108 may be formed by means of structuring (patterning) of an applied layer on the carrier 102, it being possible for the structuring to be performed by means of a chemical or physical etching process, for example by means of wet etching or wet-chemical etching, or by means of dry etching.

FIG. 4C shows a schematic cross-sectional view or side view of a chip arrangement 100 including a carrier 102, a first supporting structure 106, a second supporting structure 108, and a chip 104, the chip 104 being attached to the first supporting structure 106. Furthermore, the chip 104 may also be attached to the first supporting structure 106 by means of additional structures and by means of additional processes, for example by means of soldering, adhesive bonding, or by means of a suitable metalization process.

Furthermore, it is possible, as represented in FIG. 4D, for an antenna 212 to be formed on the carrier 102. The antenna 212 may for example be formed in the same method step as the first supporting structure 106 (for example in 310). According to various embodiments, the antenna 212 or an antenna structure may be formed by means of the same processes as the first supporting structure 106 and/or the second supporting structure 108.

According to various embodiments, the first supporting structure 106, the second supporting structure 108 and the antenna 212 may be formed by means of processes that are typical in the semiconductor industry, as described above.

Furthermore, the chip 104 may be a chip module or a flexible chip module, for example a housed chip 104, for example a flexible chip 104 in a flexible housing. Furthermore, the chip may be an ultra-thin chip or a thinned chip.

As represented in FIG. 4E, the chip 104 may be attached to the carrier 102 or to the first supporting structure 106 by means of an underfill process, by analogy with what is known as flip-chip mounting. In this case, solder balls 422 for example may provide an electrical contact structure between the chip and the carrier and/or between the chip and the antenna 212, it being possible for the chip 104 to be attached to the first supporting structure 106 by means of the underfill material 420.

Furthermore, the underfill material 420 may in this case enclose the first supporting structure 106.

According to various embodiments, the solder balls 622 may include or consist of the following materials: a solder, tin, lead, zinc, indium, carbon, gold, silver, aluminum or copper.

As represented in FIG. 4F, the chip 104 may be attached to the carrier 102 or to the first supporting structure 106 by means of a soldering process, analogous to what is known as flip-chip mounting. In this case, contact structures 424 for example may provide an electrical contact between the chip 104 and the carrier 102 and/or between the chip 104 and the antenna 212, it being possible for the chip 104 to be fastened to the first supporting structure 106 by means of a solder layer.

According to various embodiments, the antenna 212 may be formed in a region of the carrier 102 that is not strengthened by means of the supporting structures. The antenna 212 may for example be arranged in a region around the chip 104. In other words, the antenna 212 may be arranged at a lateral distance from the first supporting structure 106 and/or from the chip 104.

FIG. 5 shows by way of example the setup of a chip arrangement 100 according to various embodiments in a schematic exploded drawing.

As represented in FIG. 5 according to various embodiments, the first supporting structure 106 for example may be arranged on the first side of the carrier 102. Furthermore, the first antenna 212a may be arranged on the first side of the carrier 102, it being possible for example for the first antenna 212a to be electrically coupled (connected in a conducting manner) to the first supporting structure 106. Furthermore, a chip 104 may be arranged on the or over the first supporting structure 106, such that the chip 104 is connected to the antenna 212 in an electrically conducting manner by means of the first supporting structure 106.

According to various embodiments, consequently, the first supporting structure 106 may in addition to the stabilizing and protecting function, as described above, also serve the purpose of electrically contacting the chip 104.

Furthermore, a second antenna 212b may be arranged on the second side of the carrier 102, it being possible for the second antenna 212b to be connected to the first antenna 212a and/or to the chip 104 in an electrically conducting manner.

According to various embodiments, a second supporting structure 108 may be arranged, as described above, on the second side of the carrier, opposite from the first supporting structure 106 and/or opposite from the chip 104.

Furthermore, the first supporting structure 106 may come to lie within the chip area and be completely enclosed by the underfill.

As represented in FIG. 5, and described in detail below with reference to FIG. 6A to FIG. 6G, the second supporting structure 108 may have an edge structure that can prevent or reduce tearing of the carrier 102 on account of a mechanical load.

Furthermore, the second supporting structure 108 may be approximately the same size (lateral extent along the direction 101) as the chip area and it is possible to avoid an edge structure in the form of a straight shearing edge, formed by the first supporting structure 106 and the second supporting structure 108 and/or the chip 104.

Clearly, a lateral delimitation of the second supporting structure 108 (an edge of the second supporting structure 108) similar to the form of the edge of a postage stamp can in this case be created or provided, the “perforations” protruding beyond the chip area on the second side of the substrate. In other words, the edge region 108r of the second supporting structure 108 can extend further than the chip 104 along the direction 101, the edge region 108r of the second supporting structure 108 including a number of clearances (for example with an edge structure similar to the structure of a postage stamp).

According to various embodiments, the edge region 108r may extend into a region around the chip 104, the tear strengthening not significantly impairing the initial flexibility of the carrier in the region around the chip 104, and so the carrier can have the desired flexibility in the regions away from the chip 104.

According to various embodiments, a flexible carrier 102 or a flexible chip 104 can change its form, at least along one direction, it being possible for this deformation to be reversible, such that the chip 104 or the carrier 102 is not damaged and can in each case resume the original form.

According to various embodiments, the carrier 102 may be a film, for example a plastic film or a polymer film. Furthermore, the first supporting structure 106 may be a metal foil, for example a copper foil or an aluminum foil. Furthermore, the second supporting structure 108 may be a metal foil, for example a copper foil or an aluminum foil.

In FIG. 6A to FIG. 6G, a supporting structure 608 or strengthening structure 608, as they are described above as the first supporting structure 106 and/or as the second supporting structure 108, is respectively illustrated in detail by way of example.

FIG. 6A shows a supporting structure 608, the supporting structure 608 having an edge region 608r. Furthermore, the supporting structure 608 may include a region 608a, which does not belong to the edge region 608r. According to various embodiments, the supporting structure 608 may include a multiplicity (or plurality) of clearances in the edge region 608r of the supporting structure 608. As represented in FIG. 6A, the clearances may be arranged along at least one side of the supporting structure 608. Furthermore, the clearances may be arranged along at least two or three sides of the supporting structure 608. According to various embodiments, the clearances may be arranged along the outer periphery of the supporting structure 608.

According to various embodiments, the clearances may have a triangular form. Furthermore, as represented for example in FIG. 6B, the clearances may have a rectangular form.

According to various embodiments, seen spatially, the clearances may have a prismatic form, for example with a polygonal base area, or a cylindrical form, with a circular, round or elliptical base area. Furthermore, the clearances may be aligned in relation to the supporting structure 608 in such a way that the base area of the clearances is aligned parallel to the surface of the supporting structure 608.

FIG. 6C shows by way of example a schematic representation of a supporting structure 608 in a plan view, a multiplicity of clearances being arranged along the edge region 608r of the supporting structure 608. Furthermore, in this case the edge region 608r of the supporting structure 608, in which the clearances are arranged, forms the lateral delimitation of the supporting structure 608, for example along the lateral direction 101 and the lateral direction 105.

According to various embodiments, the supporting structure 608, as represented in FIG. 6C, may have an outer lateral delimitation that has a zigzag-shaped side face and/or side edge along a lateral direction 101, 105. Therefore, the supporting structure 608 may for example have the effect of preventing the forming of a straight shearing edge or punching edge in the chip arrangement 100.

Furthermore, the supporting structure 608 may include an inner region 608a that may serve for stabilizing and/or strengthening the carrier 102 and/or the chip 104. According to various embodiments, the chip may be arranged within the region 608a, as is described in detail with reference to FIG. 6G.

According to various embodiments, the edge region 608r of the supporting structure 608 may for example have a smaller thickness than the inner region 608a of the supporting structure 608.

According to various embodiments, the mechanical properties of the supporting structure 608 in the edge region 608r may differ from the mechanical properties of the supporting structure 608 in the inner region 608a. For example, the flexibility of the supporting structure 608 in the edge region 608r may be greater (or the stiffness less) than the flexibility (or stiffness) of the supporting structure 608 in the inner region 608a. This may for example serve the purpose that the supporting structure 608 influences the chip arrangement 100 in such a way that a tearing of the carrier 102 under a mechanical load can be prevented or reduced.

According to various embodiments, the edge region 608r of the supporting structure 608 may serve the purpose that the transition from an unsupported region of the carrier 102 to the region 102v of the carrier 102 that is supported by the supporting structure 608 can be substantially continuous, such that abrupt or step-like changes in the mechanical properties (for example stiffness) of the carrier can be avoided, and so for example the tear strength of the carrier 102 of the chip arrangement 100 can be increased.

According to various embodiments, as schematically represented in FIG. 6D in a cross-sectional view or side view, the edge region 608r of the supporting structure 608 for example may include a different material than the inner region 608a of the supporting structure 608. The material of the edge region may for example have a lower stiffness than the material of the inner region 608a of the supporting structure 608.

As schematically represented in FIG. 6E in a cross-sectional view or side view, the supporting structure 608 may be beveled in an edge region 608r of the supporting structure 608. In other words, the supporting structure 608 may have in at least one region of the edge region 608r a smaller thickness than in the inner region 608a of the supporting structure 608.

As schematically represented in FIG. 6F in a cross-sectional view or side view, the supporting structure 608 may include in an edge region 608r of the supporting structure 608 one or more clearances, the clearances partially extending into the supporting structure 608. In other words, the supporting structure 608 may have in at least one region of the edge region 608r a smaller thickness than in the inner region 608a of the supporting structure 608.

According to various embodiments, the supporting structure 608 may include an edge region 608r, it being possible for the edge region 608r to be considered as part of the supporting structure 608. In an analogous and/or similar way, according to various embodiments, a supporting structure 608 may also be surrounded by an edge structure 608r, the edge structure 608r not necessarily having to be regarded as belonging to the supporting structure 608.

As schematically represented in FIG. 6G in a cross-sectional view or side view, the chip 104 may be arranged within the region 608a of the supporting structure 608, it being possible for the edge region 608r of the supporting structure 608 to extend in a region around the chip 104. Since, seen spatially, the chip 104 may be arranged above the supporting structure 608, the relative arrangement of the chip 104 in relation to the supporting structure 608 may be illustrated by means of the projection of the chip surface 104a along the direction 103 (perpendicular to the surface 102a, 102b of the carrier 102).

According to various embodiments, the chip 104 may be arranged in relation to the supporting structure 608 or strengthening structure 608 in such a way that the projection of the chip surface 104a of the chip 104 along the direction 103 perpendicular to the surface 102a, 102b of the carrier 102 falls within the region 608a of the supporting structure 608 or of the strengthening structure 608. In other words, the region 608a of the supporting structure 608 or of the strengthening structure 608 may carry the chip 104 and stabilize the region 102v of the carrier 102, the edge region 608r of the supporting structure 608 being able to increase the tear strength of the carrier in a region around the chip 104.

According to various embodiments, the first supporting structure 106 may also have the properties and features that have been described with respect to the supporting structure 608 in FIG. 6A to FIG. 6G.

According to various embodiments, the second supporting structure 108 may also have the properties and features that have been described with respect to the supporting structure 608 in FIG. 6A to FIG. 6G.

According to various embodiments, the chip arrangement 100 may include at least one further supporting structure (in addition to the supporting structures 106, 108). Furthermore, a supporting structure 106, 108 may be made up of a number of layers or a number of regions and/or include a number of layers or a number of regions.

According to various embodiments, there is provided a carrier arrangement, which may for example be a component part of the chip arrangement 100, it being possible for the carrier arrangement to include the following: a flexible carrier 102; a first strengthening layer 106 and a second strengthening layer 108 for strengthening the flexible carrier 102, the strengthening layers 106, 108 being arranged in relation to one another on opposite sides of the carrier in such a way that the strengthening layers 106, 108 strengthen a region 102v of the carrier 102 between the strengthening layers 106, 108; the second strengthening layer including an edge region that extends further than the first strengthening layer along all directions parallel to the surface of the carrier; and the edge region of the second strengthening layer including a multiplicity of clearances.

According to various embodiments, a strengthening (or supporting) of a carrier 102 or of a chip 104 may clearly mean a mechanical strengthening, it being possible for example for the stiffness of a region of the carrier 102 or of the chip 104 to be increased, or to have been increased, and/or for example for the tear strength of the carrier 102 to be improved, such that for example the carrier 102 only tears under a greater mechanical load than without strengthening, or such that, on account of the strengthening structure, the carrier 102 at least does not tear under a lower mechanical load than without the strengthening structure.

According to various embodiments, a chip arrangement 100 may be set up in such a way that the first supporting structure 106 extends further than the chip 104 along all directions 101 parallel to the surface 102a, 102b of the carrier 102.

According to various embodiments, a chip card arrangement may be provided on the basis of the chip arrangement 100 described herein, it being possible for the chip card arrangement to include the following: a chip card housing; and a chip arrangement 100, as described above, the chip arrangement 100 being attached to the chip card housing.

According to various embodiments, the chip card housing may be an ISO chip card housing or any other desired chip card housing. Furthermore, the chip card housing may include at least one material from the following group of materials: a plastic material, a plastic, a polymer, an organic compound, wood, metal or metallic materials.

According to various embodiments, the carrier 102 may include a glass-reinforced epoxy material, for example a laminate material, for example a glass-fiber-reinforced laminate or epoxy laminate.

Furthermore, the chip 104 may include an additional outer layer, which may for example be arranged on the upper side of the chip 104. The outer layer may for example include a polymer material or a plastic, for example polyimide. Furthermore, the additional outer layer may cover a part of the surface of the chip 104. Furthermore, the outer layer may have a thickness in a range from approximately 1 μm to approximately 50 μm, for example in a range from approximately 1 μm to approximately 10 μm, for example a thickness in a range of approximately less than or equal to 10 μm. The additional outer layer may for example protect and/or mechanically stabilize the chip.

According to various embodiments, the lateral extent (for example along all directions 101 parallel to the surface 102a, 102b of the carrier 102) of the carrier 102 may be greater than the lateral extent of the chip 104 and/or the lateral extent of the supporting structures 106, 108. Furthermore, the chip 104 may be arranged substantially centrally on the carrier 102. The carrier 102 may be a film/foil or a thin layer with a rectangular form, or the carrier 102 may for example have a rectangular form with rounded corners.

According to various embodiments, the carrier 102 may have a low stiffness in a region around the chip 104, such that for example a part of the chip arrangement 100 can be very flexible, and so the chip arrangement 100 can easily deform reversibly under a mechanical load without being damaged, it being possible for a region 102v of the carrier 102 over which the chip 104 may be arranged to be strengthened by means of the supporting structures 106, 108, such that the chip 104 is better protected, the edge region of at least one of the supporting structures 106, 108 being set up in such a way that the tear strength of the carrier 102 from the edge of the supported region 102v of the carrier is improved, or at least not reduced.

According to various embodiments, the supported region 102v of the carrier 102 may be completely surrounded by an unsupported region of the carrier 102 in the lateral direction parallel to the surface of the carrier 102.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A chip arrangement, comprising:
a flexible carrier;
a first supporting structure and a second supporting structure for strengthening a region of the carrier, the first supporting structure being arranged on a first side of the carrier and the second supporting structure being arranged opposite from the first supporting structure on a second side of the carrier; and
a chip arranged on the first side of the carrier, the chip being carried and supported by means of the supporting structures and by means of the carrier;
the second supporting structure extending at least by the same amount as the chip along the directions parallel to the surface of the carrier.

2. The chip arrangement as claimed in claim 1,
the second supporting structure extending further than the chip along the directions parallel to the surface of the carrier.

3. The chip arrangement as claimed in claim 1,
the second supporting structure extending further than the first supporting structure at least along one direction parallel to the surface of the carrier.

4. The chip arrangement as claimed in claim 1, further comprising:
at least one antenna arranged on the carrier, the at least one antenna being connected in an electrically conducting manner to the chip.

5. The chip arrangement as claimed in claim 1,
the second supporting structure comprising a plurality of clearances in an edge region of the second supporting structure.

6. The chip arrangement as claimed in claim 1,
the second supporting structure extending further than the first supporting structure along all directions parallel to the surface of the carrier.

7. The chip arrangement as claimed in claim 1,
the chip extending further than the first supporting structure along all directions parallel to the surface of the carrier.

8. The chip arrangement as claimed in claim 1,
the first supporting structure being arranged between the carrier and the chip.

9. The chip arrangement as claimed in claim 1,
the first supporting structure comprising at least one metal and/or a metal alloy.

10. The chip arrangement as claimed in claim 1,
the second supporting structure comprising at least one metal and/or a metal alloy.

11. The chip arrangement as claimed in claim 1,
the first supporting structure and the second supporting structure being formed from the same material.

12. The chip arrangement as claimed in claim 4,
the first supporting structure and the second supporting structure and the at least one antenna being formed from the same material.

13. The chip arrangement as claimed in claim 1, further comprising:
a further layer arranged between the chip and the carrier, the further layer comprising at least one of at least one solder or an adhesive.

14. The chip arrangement as claimed in claim 1,
at least one of the first supporting structure or the second supporting structure having a thickness in a range from approximately 5 μm to approximately 100 μm.

15. The chip arrangement as claimed in claim 1,
the chip having a chip thickness that is equal to or less than approximately 100 μm.

16. The chip arrangement as claimed in claim 1,
the chip comprising at least one protective layer that covers at least one surface of the chip.

17. The chip arrangement as claimed in claim 16,
the at least one protective layer comprising at least one of a plastic or a polymer.

18. The chip arrangement as claimed in claim 1,
the carrier comprising at least one of a plastic or a polymer.

19. The chip arrangement as claimed in claim 1,
the carrier having a thickness in a range from approximately 1 μm to approximately 100 μm.

20. A method for manufacturing a chip arrangement, the method comprising:
forming a first supporting structure on a first surface of a carrier;
forming a second supporting structure on a surface of the carrier that is opposite from the first surface, such that a region of the carrier between the supporting structures is stabilized; and
attaching a chip on the first side of the carrier, such that the chip is carried by means of the supporting structures and by means of the carrier;
the second supporting structure extending at least by the same amount as the chip along the directions parallel to the surface of the carrier.

21. The chip arrangement as claimed in claim 20,
the forming of the second supporting structure and the attachment of the chip being performed in such a way that the second supporting structure extends further than the chip along at least one direction parallel to the surface of the carrier.

22. The chip arrangement as claimed in claim 20,
the forming of the first supporting structure and the forming of the second supporting structure being performed in such a way that the second supporting structure extends further than the first supporting structure along at least one direction parallel to the surface of the carrier.

23. The chip arrangement as claimed in claim 20, further comprising:
the forming of at least one antenna on the carrier, such that the at least one antenna has an electrically conductive connection to the chip.

24. A chip card arrangement, comprising:
a chip card housing; and
a chip arrangement, comprising
a flexible carrier;
a first supporting structure and a second supporting structure for strengthening a region of the carrier, the first supporting structure being arranged on a first side of the carrier and the second supporting structure being arranged opposite from the first supporting structure on a second side of the carrier; and
a chip arranged on the first side of the carrier, the chip being carried and supported by means of the supporting structures and by means of the carrier;
the second supporting structure extending at least by the same amount as the chip along the directions parallel to the surface of the carrier;
at least one antenna arranged on the carrier, the at least one antenna being connected in an electrically conducting manner to the chip;
wherein the chip arrangement is attached to the chip card housing.

25. The chip card arrangement as claimed in claim 24,
the chip card housing comprising at least one antenna, which is inductively coupled to the at least one antenna of the chip arrangement.
